(19) United States
(12) Patent Application Publication
(10) Pub. No.: US 2011/0273430 A1
(43) Pub. Date: Nov. 10, 2011

(54) VOLTAGE LEVEL SHIFTING WITH REDUCED POWER CONSUMPTION

(75) Inventors: Chor Yin Chia, San Jose, CA (US); Hong Joong Kim, San Jose, CA (US)

(73) Assignee: INTERSIL AMERICAS INC., Milpitas, CA (US)

(21) Appl. No.: 13/021,623

(22) Filed: Feb. 4, 2011

Related U.S. Application Data
(60) Provisional application No. 61/331,512, filed on May 5, 2010.
(60) Provisional application No. 61/334,133, filed on May 12, 2010.

(51) Int. Cl. G06F 3/038; H03L 5/00

(52) U.S. Cl. 345/212; 327/333

(57) ABSTRACT

In an embodiment, a voltage level shifter circuit includes a first terminal configured to be connected to a high voltage supply rail (Vs+), a second terminal configured to be connected to a low voltage supply rail (Vs−), and an output voltage (V_{OUT}) terminal. The voltage level shifter can also include a compensation voltage (V_{COMP}) node. Additionally, the voltage level shifter includes a plurality of switches configurable in a plurality of configurations, and control circuitry configured to control the switches so that in at least one of the configurations a load connected to the output voltage (V_{OUT}) terminal does not draw any power from the low voltage supply rail (Vs−) and the high voltage supply rail (Vs+). The load can be, e.g., a gate drive circuit of a display panel, such as a thin film transistor-liquid crystal display (TFT-LCD) panel, but is not limited thereto.

### PRIORITY CLAIM

This application claims priority under 35 U.S.C. 119(e) to U.S. Provisional Patent Application No. 61/331,512 entitled VOLTAGE LEVEL SHIFTING WITH REDUCED POWER CONSUMPTION, filed May 5, 2010, and U.S. Provisional Patent Application No. 61/334,133 entitled VOLTAGE LEVEL SHIFTING WITH REDUCED POWER CONSUMPTION, filed May 12, 2010, each of which is incorporated herein by reference.

### BACKGROUND

Thin film transistor (TFTs) integrated on glass are being used to manufacture liquid crystal display (LCD) panels. A TFT integrated on glass has a much slower mobility than a regular NMOS transistor or PMOS transistor (collectively referred to as a regular N/PMOS transistor). Normally, a regular N/PMOS transistor typically has a threshold voltage in the range of 0.7˜3V. To turn on the regular N/PMOS transistor, a gate source voltage (Vgs) must be greater than the threshold voltage (Vthreshold). By contrast, due to poor mobility a TFT has a significantly higher threshold voltage than a regular N/PMOS transistor. Accordingly, a TFT requires a very high gate source voltage, and thus a very high voltage applied to its gate. The required gate source voltage is different for different LCD manufacturers, but most TFTs require a gate source voltage within the range of 30V˜60V. Accordingly, voltage level shifters are often used for generating the voltage levels necessary to drive the gates of such TFTs integrated on glass.

FIG. 1 illustrates an exemplary high level circuit for a conventional voltage level shifter 102. Referring to FIG. 1, the conventional voltage level shifter 102 is shown as including a first switch S1 connected between a high voltage supply rail Vs+ and the voltage output V_{OUT} node, and a second switch S2 connected between a low voltage supply rail Vs− and the voltage output V_{OUT} node. At the left in FIG. 1 is shown a first configuration (config 1) where S1 is open and S2 is closed, which causes V_{OUT} to be pulled down to Vs−. At the right in FIG. 1 is shown a second configuration (config 2) where S1 is closed and S2 is open, which causes V_{OUT} to be pulled up to Vs+.

FIG. 2 illustrates a plot of an exemplary output voltage that can be achieved at the voltage output node V_{OUT} of FIG. 1. For FIG. 2, it is assumed that Vs−=−15V, and Vs+=+20V. As can be appreciated from FIG. 2, the voltage level shifter 102 alternates between config 1 and config 2, which causes V_{OUT} to alternate between being pulled down to Vs− and being pulled up to Vs+. In FIG. 2, the voltage shift V_{SHIFT} at V_{OUT} is 35V.

The equation P=C*V_{SHIFT}\hat{0}2*F specifies the power consumed (P) by a voltage level shifter, such as the voltage level shifter 102 shown in FIG. 1. Here C is the capacitance of the capacitive load (C_{LOAD}) of the LCD panel, V_{SHIFT} is the voltage shift provided by the voltage level shifter (which is Vs+−Vs− for the voltage level shifter 102 in FIG. 1), and F is the operating frequency of the voltage level shifter. In this equation, for a specific LCD panel, C and F are fixed, but V_{SHIFT} is variable. Further, as can be appreciated from this equation, if the V_{SHIFT} is changed, the power consumption is changed by V_{SHIFT}\hat{0}2 (i.e., V_{SHIFT} squared).

Referring again to FIG. 2, Vs+ is shown as +20V and Vs− is shown as −15V. This means that V_{SHIFT}=35V. Thus, for this example, P=C*35̂2*F. An exemplary value for C=4.7 nF, and an exemplary value for F=129 kHz (e.g., assuming a frame rate of 120 Hz and 1080 rows, then F=120 Hz*1080 rows=129 kHz frequency).

Package temperature is a function of power consumption. LCD panel manufactures would prefer to reduce package temperatures and power consumption associated with voltage level shifter chips.

### SUMMARY

In accordance with an embodiment, a voltage level shifter circuit (e.g., 302 in FIG. 3) includes a first terminal configured to be connected to a high voltage supply rail (Vs+), a second terminal configured to be connected to a low voltage supply rail (Vs−), an output voltage (V_{OUT}) terminal, and a compensation voltage (V_{COMP}) node. Additionally, the voltage level shifter includes a plurality of switches configurable in a plurality of configurations, and control circuitry configured to control the switches so that in at least one of the configurations a load connected to the output voltage (V_{OUT}) terminal does not draw any power from the low voltage supply rail (Vs−) and the high voltage supply rail (Vs+). The load can be, e.g., a portion of thin film transistor-liquid crystal display (TFT-LCD) panel, but is not limited thereto.

In accordance with an embodiment, the plurality of switches include a first switch (S1), a second switch (S2) and a third switch (S3). The first switch (S1) is connected between a first terminal and the output voltage (V_{OUT}) terminal, wherein the first terminal is configured to be connected to the high voltage supply rail (Vs+). The second switch (S2) is connected between a second terminal and the output voltage (V_{OUT}) terminal, wherein the second terminal is configured to be connected to the low voltage supply rail (Vs−). The third switch (S3) is connected between the compensation voltage (V_{COMP}) node and the output voltage (V_{OUT}) terminal. The control circuitry is configured to control the first, second and third switches (S1, S2 and S3) so that they transition between first, second, third and fourth configurations. In the first configuration (config 1) the first switch (S1) is opened, the second switch (S2) is closed, and the third switch (S3) is opened, which causes the output voltage (V_{OUT}) terminal to be pulled down to the low voltage supply rail (Vs−). In the second configuration (config 2) the first (S1) is opened, the second switch (S2) is opened, and the third switch (S3) is closed, which causes the output voltage (V_{OUT}) terminal to be pulled up to a first intermediate voltage level between the low voltage supply rail (Vs−) and the high voltage supply rail (Vs+). In the third configuration (config 3) the first switch (S1) is closed, the second switch (S2) is opened, and the third switch (S3) is opened, which causes the output voltage (V_{OUT}) terminal to be pulled up to the high voltage supply rail (Vs+). In the fourth configuration (config 4) the first switch (S1) is opened, the second switch (S2) is opened, and the third switch (S3) is closed, which causes the output voltage (V_{OUT}) terminal to be pulled down to a second intermediate voltage level between the low voltage supply rail (Vs−) and the high voltage supply rail (Vs+).

During the second and fourth configurations (config 2 and config 4) the voltage level shifter circuit does not draw any power from the low voltage supply rail (Vs−) and the high voltage supply rail (Vs+). Further, during the second and fourth configurations (config 2 and config 4) a load connected to the output voltage (V_{OUT}) terminal does not draw any power from the low voltage supply rail (Vs−) and the high voltage supply rail (Vs+).

In accordance with an embodiment, the first intermediate voltage level equals (Vs−+V_{COMP})/2, and the second intermediate voltage level equals (Vs++V_{COMP})/2.

In accordance with an embodiment, at least a compensation capacitor (C_{COMP}) is to be connected between the compensation voltage (V_{COMP}) node and a further voltage rail between the high and low voltage supply rails. Additionally, a compensation resistor (R_{COMP}) can be connected in series with the compensation capacitor (C_{COMP}) between the compensation voltage (V_{COMP}) node and the further voltage rail. The further voltage rail can be ground, or some other voltage rail or level between Vs− and Vs+. A voltage at the compensation voltage (V_{COMP}) node is dependent on the compensation capacitor (C_{COMP}) connected between the compensation voltage (V_{COMP}) node and the further voltage rail.

The compensation resistor (R_{COMP}) and the compensation capacitor (C_{COMP}) are exemplary components of compensation circuitry connected between the compensation voltage (V_{COMP}) node and the further voltage rail. In accordance with specific embodiments, such compensation circuitry is external to a display panel (e.g., a LCD panel) that is being driven by the voltage level shifter. By having the compensation circuitry external the LCD panel, this enables the intermediate voltage levels generated at the V_{COMP} node to be precisely controlled to provide for optimal power savings and/or other customization without requiring modification of the LCD panel. In other words, this enables the voltage level shifter to be used with various different LCD panels (e.g., manufactured by various different manufacturers), while still allowing the intermediate voltage levels generated at the V_{COMP} node to be readily optimized or otherwise customized for different LCD panels, without requiring the manufacturers of the LCD panels to modify their LCD panels.

In accordance with an embodiment, the first switch (S1), the second switch (S2), the third switch (S3) and the control circuitry are implemented within an integrated circuit (IC), and each one of the first terminal, the second terminal, the output voltage (V_{OUT}) terminal, and the compensation voltage (V_{COMP}) node is a separate terminal of the IC. In such an embodiment, the control circuitry can be configured to transition between the first, second, third and fourth configurations in dependence on one or more clock signals that are provided to one or more clock input terminals of the IC.

In accordance with an embodiment, a voltage at the compensation voltage (V_{COMP}) node is provided by a power supply. In such an embodiment, the voltage at the compensation voltage (V_{COMP}) node, which is provided by the power supply, can equal (Vs++Vs−)/2, but is not limited thereto.

In accordance with an embodiment, a method for voltage level shifting includes: during a first period of time, pulling the output voltage (V_{OUT}) terminal down to the low voltage supply rail (Vs−); during a second period of time, pulling the output voltage (V_{OUT}) terminal up to a first intermediate voltage level between the low voltage supply rail (Vs−) and the high voltage supply rail (Vs+); during a third period of time, pulling the output voltage (V_{OUT}) terminal up to the high voltage supply rail (Vs+); and during a fourth period of time, pulling the output voltage (V_{OUT}) terminal down to a second intermediate voltage level between the low voltage supply rail (Vs−) and the high voltage supply rail (Vs+). In accordance with an embodiment, the method described above can be used for providing voltage level shifting for use in driving a display panel, such as, but not limited to a TFT-LCD panel. In accordance with specific embodiments, the method also includes generating the first and second intermediate voltage levels using circuitry that is completely to the display panel. This enables the intermediate voltage levels to be precisely controlled, thereby providing for power savings optimization and/or other customization when using these methods with various different display panels (e.g., manufactured by various different manufacturers).

This summary is not intended to summarize all of the embodiments of the present invention. Further and alternative embodiments, and the features, aspects, and advantages of the embodiments of invention will become more apparent from the detailed description set forth below, the drawings and the claims.

### BRIEF DESCRIPTION OF THE DRAWINGS

FIG. 1 illustrates an exemplary high level circuit for a conventional voltage level shifter.

FIG. 2 illustrates a plot of an exemplary output voltage that can be achieved at the voltage output node of the conventional voltage level shifter of FIG. 1.

FIG. 3 illustrates four different configurations of a voltage level shifter, according to an embodiment of the present invention.

FIGS. 4 and 5 illustrate plots of exemplary output voltages that can be achieved at the voltage output node of the voltage level shifter of FIG. 3.

FIG. 6 illustrates a voltage level shifter that is an exemplary implementation of the voltage level shifter introduced in FIG. 3, according to an embodiment of the present invention.

FIG. 7 is a timing diagram for the voltage level shifter of FIG. 6.

FIG. 8A illustrates four different configurations of a voltage level shifter, according to another embodiment of the present invention.

FIG. 8B illustrates a voltage level shifter, according to still another embodiment of the present invention.

FIG. 9 illustrates a voltage level shifter that is an exemplary implementation of the voltage level shifter introduced in FIG. 8A, according to an embodiment of the present invention.

FIG. 10 illustrates an exemplary system in which voltage level shifters, according to embodiments of the present invention, can be used.

FIG. 11 is a high level flow diagram that is used to summarize methods according to certain embodiments of the present invention.

### DETAILED DESCRIPTION

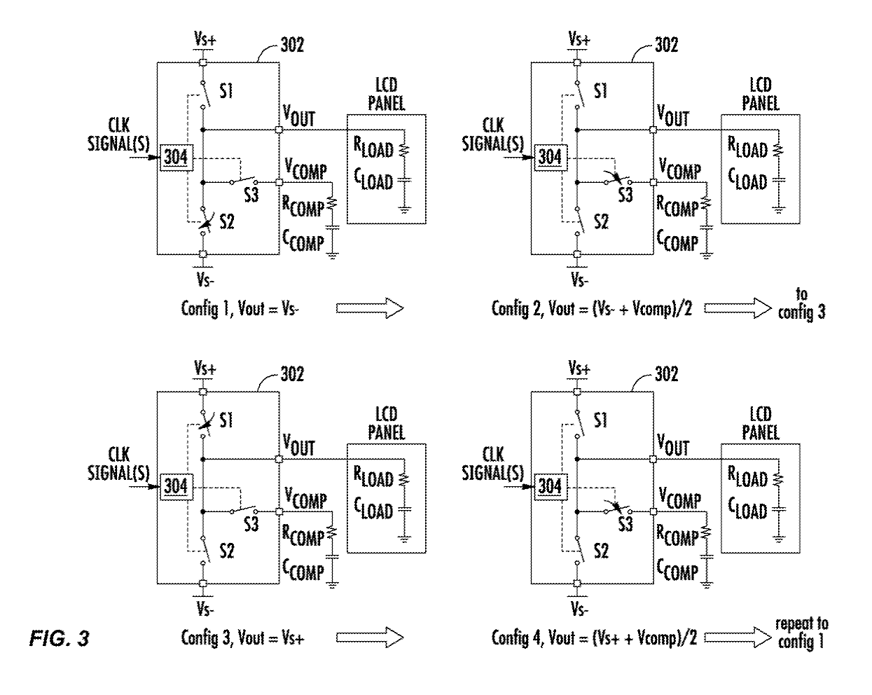

FIG. 3 illustrates four different configurations of a voltage level shifter 302, according to an embodiment of the present invention. Referring to FIG. 3, the voltage level shifter 302 is shown as including a first switch S1 connected between a high voltage supply rail Vs+ and the voltage output V_{OUT} node, and a second switch S2 connected between a low voltage supply rail Vs− and the voltage output V_{OUT} node. Additionally, a third switch S3 is connected between a compensation voltage V_{COMP} node and the voltage output V_{OUT} node. A compensation resistor R_{COMP} and a compensation capacitor C_{COMP} are shown as being connected in series between the compensation voltage V_{COMP} node and ground, or some other voltage rail or level that is between Vs− and Vs+. Thus, the switch S1 selectively connects V_{OUT} to the high voltage supply rail Vs+, the switch S2 selectively connects V_{OUT} to the low voltage supply rail Vs−, and the switch S3 selectively connects V_{OUT} to V_{COMP}.

The voltage level shifter 302 is also shown as including control circuitry 304 that selectively controls the switches S1, S2 and S3. In view of the below description of the operation of the control circuitry 304, one of ordinary skill in the art would appreciate that the control circuitry 304 can be implemented in numerous different manners that are within the scope of the present invention. For example, such control circuitry 304 can include delay lines, one-shots, flip-flops, logic gates (e.g., AND, OR, NAND, NOR, XOR, etc. gates), and the like. Further, one of ordinary skill in the art will appreciate from the discussion below that the control circuitry 304 can be itself controlled in dependence on one or more clock signals. Such clock signals can be generated using timing circuitry that is external to the voltage level shifter 302. Alternatively, the clock signals can be generated using timing circuitry that is integrated into the voltage level shifter 302.

At the upper left in FIG. 3 is shown a first configuration (config 1) where the first switch S1 is opened, the second switch S2 is closed, and the third switch S3 is opened, which causes V_{OUT} to be pulled down to the low voltage supply rail Vs−. At the upper right in FIG. 3 is shown a second configuration (config 2) where the first S1 is opened, the second switch S2 is opened, and the third switch S3 is closed, which causes V_{OUT} to be pulled up to a first intermediate voltage level between the low voltage supply rail Vs− and the high voltage supply rail Vs+, where the first intermediate voltage level is (Vs−+V_{COMP})/2. At the lower left in FIG. 3 is shown a third configuration (config 3) where the first switch S1 is closed, the second switch S2 is opened, and the third switch S3 is opened, which causes V_{OUT} to be pulled up further to the high voltage supply rail Vs+. At the lower right in FIG. 3 is shown a fourth configuration (config 4) where the first switch S1 is opened, the second switch S2 is opened, and the third switch S3 is closed, which causes V_{OUT} to be pulled down to a second intermediate voltage level between the low voltage supply rail Vs− and the high voltage supply rail Vs+, where the second intermediate voltage level equals (Vs++V_{COMP})/2. Thereafter, the voltage level shifter goes back to the first configuration and the above changes in configurations repeat. The first, second, third and fourth configurations of the voltage level shifter 302 can also be referred to as first, second, third and fourth phases of the voltage level shifter 302.

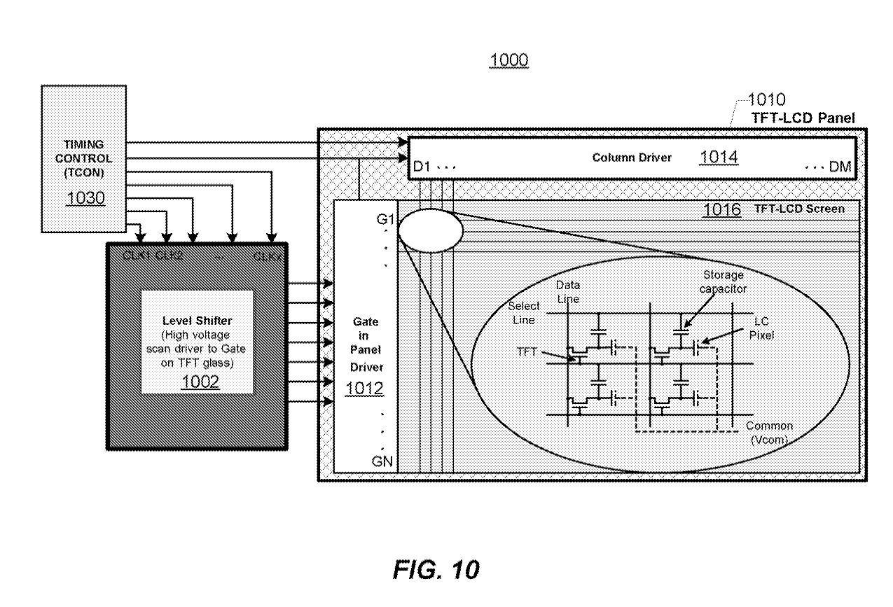

As will be explained in more detail below, with reference to FIG. 10, the voltage level shifter 302 can be used to drive a high voltage shift register within a gate driver of an LCD panel, with R_{LOAD} and C_{LOAD} representing lump sum resistances and capacitances of a high voltage shifter register of the gate driver.

As can be appreciated from FIG. 3, the V_{COMP} node is for connection to compensation circuitry, external to the LCD panel. The compensation circuitry is shown as including C_{COMP} connected between the V_{COMP} node and ground, or some alternative further voltage rail between the high and low voltage supply rails. In the embodiment of FIG. 3, the compensation circuitry also includes R_{COMP} connected in series with the C_{COMP}. Alternative configurations of the compensation circuitry are possible and within the scope of the present invention.

The voltage at the V_{COMP} node, which can be referred to simply as V_{COMP}, is dependent on the values of R_{COMP}, C_{COMP} of the compensation circuitry and R_{LOAD} and C_{LOAD} of the LCD panel. V_{COMP} is also dependent on the switch resistance of the switch S3, as well as the control of the switch S3, including the operating frequency and duty cycle of the signal that controls the switch S3. Assuming R_{LOAD} and C_{LOAD} of the LCD panel are constants defined by an LCD manufacturer, V_{COMP} can be adjusted by adjusting C_{COMP} and R_{COMP} of the compensation circuitry. By having the compensation circuitry external the LCD panel, this enables the intermediate voltage levels generated at the V_{COMP} node to be precisely controlled to provide for optimal power savings and/or other customization without requiring modification of the LCD panel. In other words, this enables the voltage level shifter to be used with various different LCD panels (e.g., manufactured by various different manufacturers), while still allowing the intermediate voltage levels generated at the V_{COMP} node to be readily optimized or otherwise customized for different LCD panels, without requiring the manufacturers of the LCD panels to modify their LCD panels. Additional details of how the voltage level shifter achieves power savings are provided below.

The voltage level shifter 302 of FIG. 3 enables power consumption to be reduced by adding the voltage level V_{COMP} using the compensation capacitor C_{COMP}. The compensation capacitor C_{COMP} stores charge from, and discharges charge to, the LCD panel. The compensation resistor R_{COMP} controls the current flowing into and out of the compensation capacitor C_{COMP}. Instead of switching the voltage output node V_{OUT} from the voltage of the low voltage supply rail Vs− directly to the voltage of the high voltage supply rail Vs+, the voltage shift from Vs− to Vs+ occurs in two steps. More specifically, in accordance with an embodiment, there is a voltage shift from Vs− to (Vs−+V_{COMP})/2, and there is a voltage shift from (Vs−+V_{COMP})/2 to Vs+. Additionally, instead of switching the voltage output node V_{OUT} from the voltage of the high voltage supply rail Vs+ directly to the voltage of the low voltage supply rail Vs+, the shift from Vs+ to Vs− occurs in two steps. More specifically, in accordance with an embodiment, there is a shift from Vs+ to (Vs++V_{COMP})/2, and there is a shift from (Vs++V_{COMP})/2 to Vs−.

It can be appreciated from FIG. 3 that during the second configuration (config 2) and the fourth configuration (config 4), V_{OUT}, and thus the LCD panel connected to V_{OUT}, is disconnected from both the high voltage supply rail Vs+ and the low voltage supply rail Vs−. Thus, during config 2 and config 4 there is no power drawn from the high and low voltage supply rails. Rather, the voltages provided to V_{OUT}, and thus to LCD panel connected to V_{OUT}, during config 2 and config 4 result from the passive capacitances C_{COMP} and C_{LOAD}.

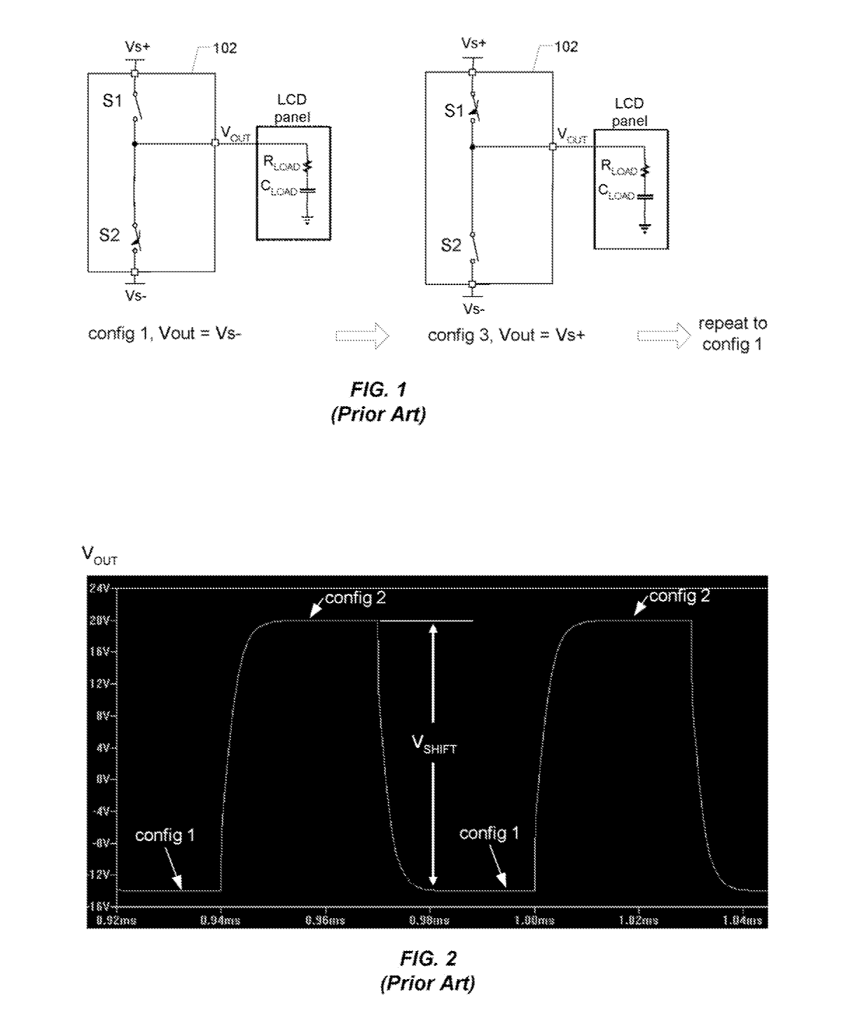

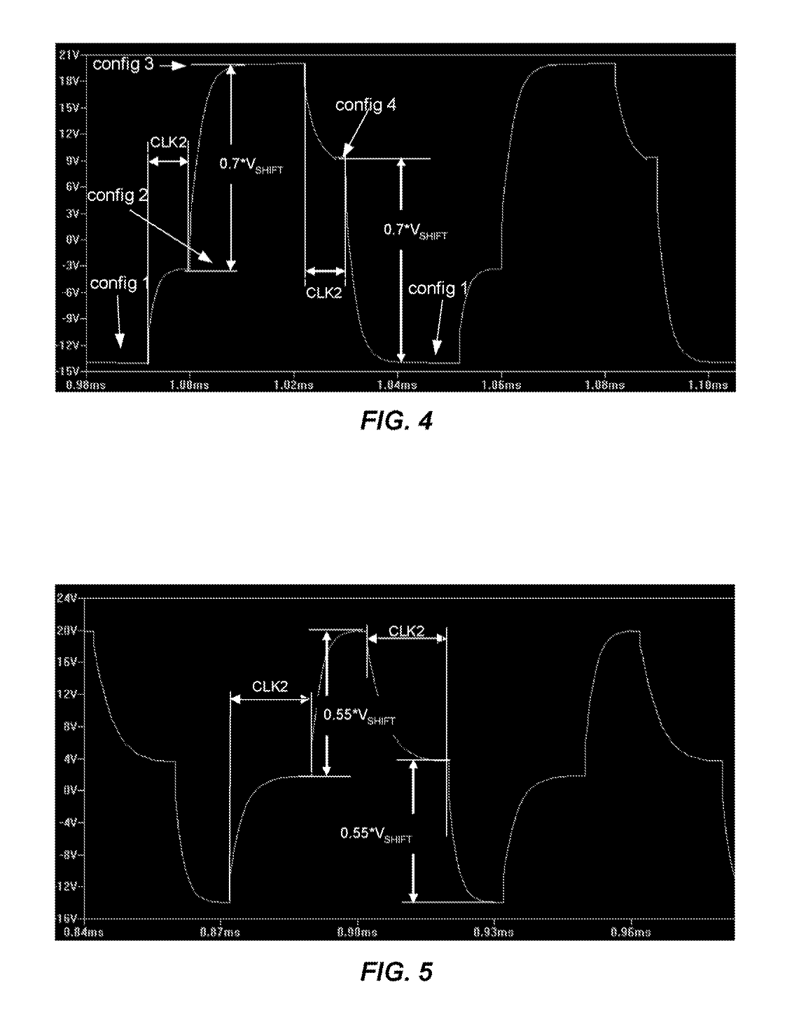

FIGS. 4 and 5 illustrate plots of exemplary output voltages that can be achieved at the voltage output node V_{OUT} of FIG. 3 using the voltage level shifter 302 of FIG. 3. In order to provide for an easy comparison between the embodiments described with reference to FIGS. 3-5 and the prior art described with reference to FIGS. 1 and 2, in FIGS. 3-5 it is again assumed that Vs−=−15V, and Vs+=+20V.

In the plot of FIG. 4, the portion of V_{SHIFT} where power is drawn from either the high voltage supply rail Vs+ or the low voltage supply rail Vs− is only 0.7*V_{SHIFT}. As explained above, for the prior art level shifter 102 described with reference to FIGS. 1 and 2, the power consumed by the level shifter 102 was P=C*V_{SHIFT}\hat{0}2*F. By comparison, in the embodiment described with reference to FIGS. 3 and 4, P=C*(0.7*V_{SHIFT})̂2*F=C*0.49*V_{SHIFT}*F, which is an approximately 50% reduction in power consumption compared to the prior art voltage level shifter 102 described with reference to FIGS. 1 and 2.

As explained above, V_{COMP} can be adjusted by adjusting C_{COMP} and R_{COMP}. Such an adjustment to V_{COMP} can be used to adjust the power consumption of the level shifter 302, as will now be explained with reference to FIG. 5. By selecting appropriate values for C_{COMP} and R_{COMP}, a V_{COMP} can be achieved that results in the portion of V_{SHIFT} where power is drawn from either the high voltage supply rail Vs+ or the low voltage supply rail Vs− to be only 0.55*V_{SHIFT}. Thus, by selecting appropriate values for C_{COMP} and R_{COMP} for the embodiment of FIGS. 3 and 5, P=C*(0.55*V_{SHIFT})̂2*F=C*0.30*V_{SHIFT}*F, which is an approximately 70% reduction in power consumption compared to the prior art voltage level shifter 102 described with reference to FIGS. 1 and 2.

In accordance with certain embodiments, the voltage level shifter 302 (or other embodiments of the voltage level shifter) is implemented as an integrated circuit (IC), which is also known as a chip. In such embodiments, the voltage output node V_{OUT} can be a terminal (e.g., pin) of the IC, and the compensation voltage node V_{COMP} can be another terminal (e.g., pin) of an IC. A further pair of terminals of the IC can be for connection to the high and low voltage rails (Vs+ and Vs−). One or more further terminals of the IC can accept one or more control signals, which can include one or more clock signals, but is not limited thereto. More specifically, in accordance with certain embodiments, switches S1, S2 and S3 are integrated within an integrated circuit (IC) along with the control circuitry 304 that can be used to control switches S1, S2 and S3 in response to receiving one or more clock signals. In such embodiments, the voltage level shifter IC can include a terminal (e.g., a pin) that is to be connected to a high voltage supply rail, a terminal that is to be connected to a low voltage supply rail, an output terminal that provides V_{OUT}, and a further terminal (which can be referred to as the V_{COMP} terminal) to which a series connected (or otherwise connected) C_{COMP} and R_{COMP} can be connected, as can be appreciated from FIG. 3. The voltage level shifter IC can also include one or more clock input terminals that accepts one or more clock signals. A terminal, as the term is used herein, is a node that connects a circuit (which may, or may not be an integrated circuit) to other (e.g., external) circuitry. Terminals of a voltage level shifter can, for example, be connected to voltage rails, receive control signals, or be connected to a load (e.g., a portion of a TFT-LCD panel) that is driven by the voltage level shifter.

In alternative embodiments, C_{COMP} and R_{COMP} and/or other compensation circuitry are integrated within the voltage level shifter IC and may be programmable (e.g., by using a bank of selectable capacitors and a bank of selectable resistors). It is also possible that the timing circuitry used to generate the one or more clock signals used to control the control circuitry 304 be integrated within the voltage level shifter IC.

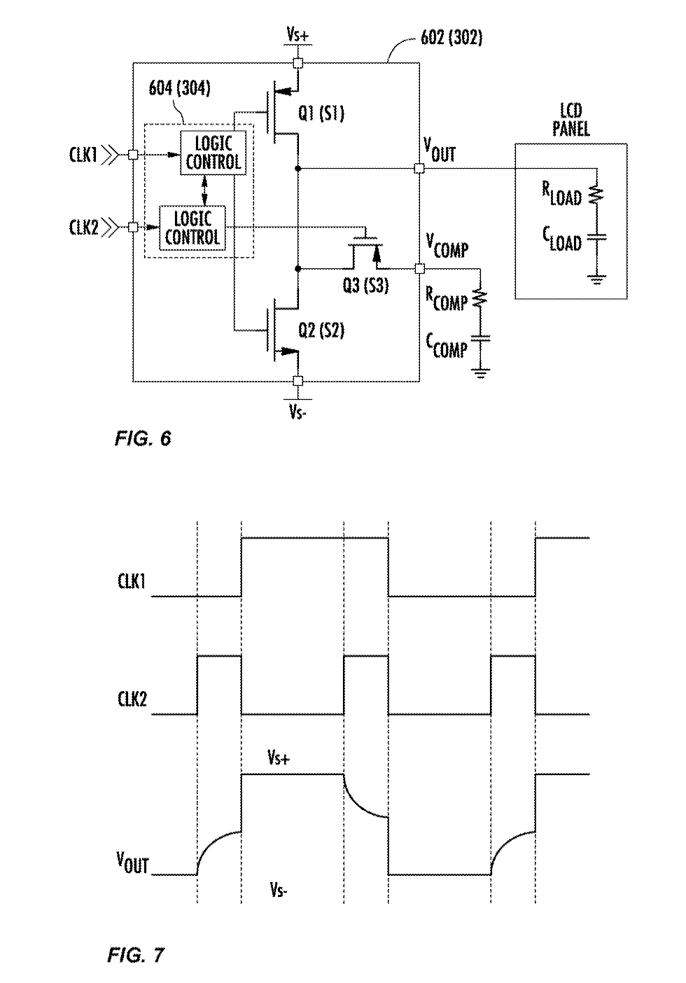

FIG. 6 illustrates a voltage level shifter 602 that is an exemplary implementation of the voltage level shifter 302, according to an embodiment of the present invention. Referring to FIG. 6, switches S1, S2 and S3 are implemented, respectively, by transistors Q1, Q2 and Q3. Q1 is shown as a PMOS transistor having its source connected to the high voltage supply rail Vs+, its drain connected to V_{OUT}, and its gate driven by control circuitry 604. Q2 is shown as an NMOS transistor having its source connected to the low voltage supply rail Vs−, its drain connected to V_{OUT}, and its gate drive by control circuitry 604. Q3 is shown as a PMOS, with its source connected to V_{COMP}, its drain connected to V_{OUT} and its gate driven by the control circuitry 604. The control circuitry 604, which is an implementation of the control circuitry 304, is shown as receiving two clock signals CLK1, CLK2, but it can receive more or less clock signals, depending on the implementation of the control circuitry 604. The control circuitry 604 can include logic control blocks, as shown in FIG. 6. Further, it is noted that the switches can be implemented in other manners, e.g., using other types of transistors, including, but not limited to, BJTs, FETs and JFETs, while still being within the scope of the present invention.

FIG. 7 is a timing diagram for the voltage level shifter 604 of FIG. 6, which shows how V_{OUT} can be produced using two clock signals CLK1 and CLK2. In the exemplary embodiment described with reference to FIGS. 6 and 7, CLK1 controls the switching transistors Q1 and Q2 (which implement switches S1 and S2), and CLK2 controls the switching transistor Q3 (which implements switch S3). As can be appreciated from FIG. 7, in such a configuration, the frequency and duty cycle of CLK2 controls when there is a voltage level shift at V_{OUT} from one of the voltage supply rails (Vs− or Vs+) to an intermediate voltage level that is dependent on V_{COMP}. Referring back to FIGS. 4 and 5, also shown in these plots was how a CLK2 can be used to control when there is a voltage level shift at V_{OUT} from one of the voltage supply rails (Vs− or Vs+) to an intermediate voltage level that is dependent on V_{COMP}.

There are many different combinations of input signals (e.g., CLK1 and CLK2) that can be used to operate this circuit. However, the timing diagram shown in FIG. 7 has been provided to show one example of the input signals can be used to control the output of the voltage level shifter 602. Since the required output timing can be different for different applications, the adjustable timing achieved using two clock signals and the power saving feature in this architecture makes for this voltage level shifter useful for various applications, e.g., for use with various different LCD panels.

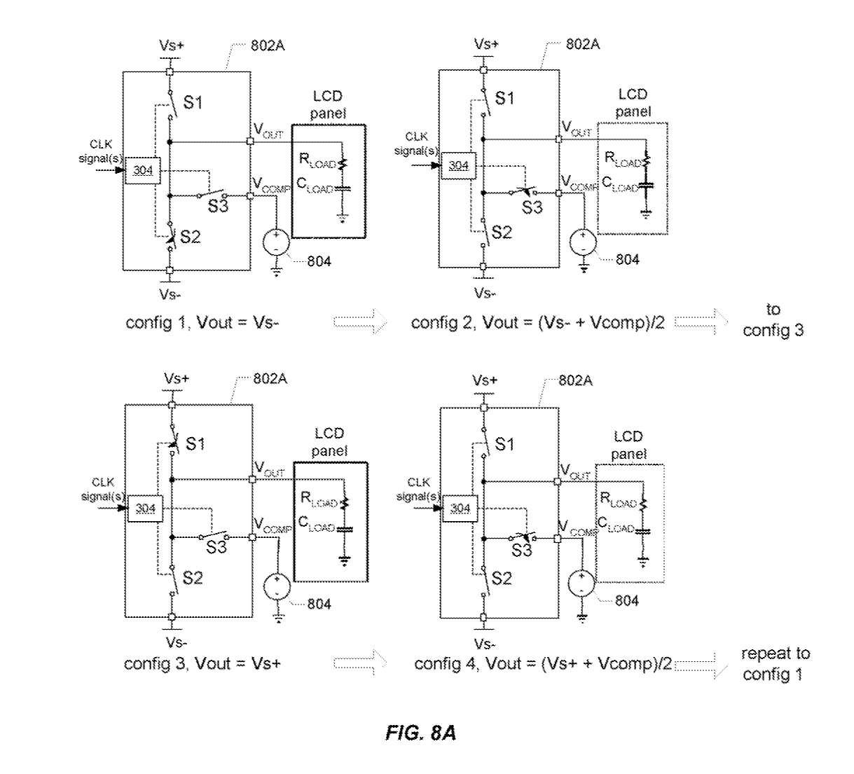

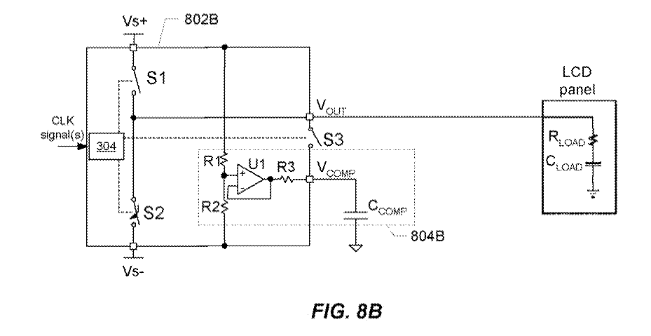

FIG. 8A illustrates four different configurations of a voltage level shifter 802A, according to another embodiment of the present invention. Here, instead of using C_{COMP} to produce V_{COMP} (to reduce power consumption compared to the voltage level shifter 102 of FIG. 1), a power supply 804A is used to provide V_{COMP}. This will still provide for reduced power consumption compared to the voltage level shifter 102 of FIG. 1, but potentially not as much a reduction in power consumption as the voltage level shifter 302 introduced in FIG. 3. In accordance with an embodiment, V_{COMP}=(Vs++Vs−)/2. In accordance with other embodiments, V_{COMP} is some other voltage between Vs+ and Vs−. The power consumption for the voltage level shifter 802A can be expressed as P=(4*C(V_{SHIFT}/2)*(V_{SHIFT}/2)*F)/2. Where V_{COMP}=(Vs++Vs−)/2, then P=(C*V_{SHIFT}̂2*F)/2, which is a 50% reduction in power consumption compared to the voltage level shifter 102 of FIG. 1. The control circuitry 304 and switches S1, S2 and S3 in FIG. 8A operate in a similar manner as in FIG. 3, and thus, need not be explained in detail again.

In accordance with an embodiment of the present invention, rather than using an external power supply to produce V_{COMP}, as was the case in FIG. 8A, the power supply (or at least a portion thereof) can be integrated with the voltage level shifter. This will be explained with reference to the voltage level shifter 802B shown in FIG. 8B. Referring to FIG. 8B, a resistor divider including resistors R1 and R2 produces a voltage that is provided to a non-inverting (+) input of an amplifier U1 configured as a buffer, i.e., the output of the amplifier is connected to the inverting (−) input of the amplifier. A compensation capacitor C_{COMP} is connected to V_{COMP}. The buffer configured amplifier U1 provides a stable DC voltage level to the compensation capacitor C_{COMP}. A further resistor R3 can be connected between the output of the amplifier U1 and the V_{COMP} node to limit the current provided to the compensation capacitor C_{COMP}. In accordance with an embodiment, the capacitance of C_{COMP} is at least 100× the capacitance of C_{LOAD}. The compensation capacitor C_{COMP} is shown as being external the voltage level shifter, but can alternatively be integrated therein. In these embodiments, the resistors R1, R2, R3, the amplifier U1 and the compensation capacitor C_{COMP} provide a power supply 804B. In accordance with a specific embodiment, the power supply 804B is configured to cause V_{COMP} to equal (Vs++Vs−)/2, although in alternative embodiments V_{COMP} can be driven to another voltage. Only one configuration of the switches S1, S2 and S3 are shown in FIG. 8B, but as was the case with previous described embodiments, these switches have four configurations. The control circuitry 304 and switches S1, S2 and S3 in FIG. 8B operate in a similar manner as in FIG. 3, and thus, need not be explained in detail again. In accordance with other embodiments, the buffered amplifier U1 and resistors R1, R2 and R3 can be replaced with a DC-DC switching power supply, or a low drop-out (LDO) regulator, but is not limited thereto.

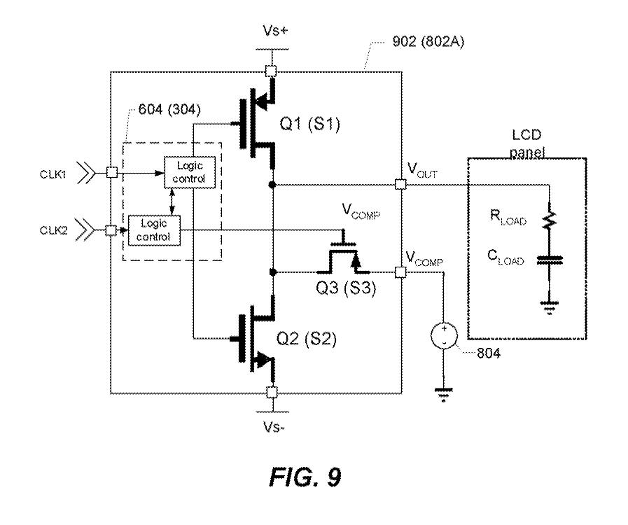

FIG. 9 illustrates a voltage level shifter 902 that is an exemplary implementation of the voltage level shifter 802A, according to an embodiment of the present invention. A similar implementation can be used for the voltage level shifter 802B.

The voltage level shifters described herein generate a single ended voltage signal at their V_{OUT} terminal. Accordingly, the voltage level shifters described herein can be used to drive a load, such as a portion of a TFT-LCD panel, that accepts a single ended drive signal. If the load to be driven requires a differential signal, the single ended voltage signal at the V_{OUT} terminal can be converted to a differential signal using a single ended-to-differential signal converter. Alternatively, a pair of voltage level shifters can be used to generate complementary singled ended signals that collectively provide a differential signal.

FIG. 10 illustrates an exemplary system in which voltage level shifters, according to embodiments of the present invention, can be used. More specifically, FIG. 10 is a high level diagram of a gate in panel (GIP) TFT-LCD system 1000. The GIP TFT-LCD system 1000 is shown as including a TFT-LCD panel 1010, a timing controller (TCON) 1020 and a voltage level shifter 1002. The TFT-LCD panel 1010 is shown as including a gate in panel (GIP) driver 1012, a column driver 1014, and a TFT-LCD screen 1016.

The GIP driver 1012, which is a type of gate line driver (which is also known as a row driver), includes a high voltage shift register that can be driven by one or more voltage level shifter 1002 of an embodiment of present invention described above. The column driver 1014 is also sometimes referred to as a data drive circuit, or as a source line driver. The TFT-LCD screen 1016 includes gate lines G1 to GN and data lines D1 to DM, which cross each other. At the crossing of each gate line G1 to GN and each data line D1 to DM is a thin film transistor (TFT), e.g., a polysilicon or a-Si TFT. The gate of a TFT is connected to one of the gate lines G1 to GN, the source of the TFT is connected to one of the data lines D1 to DM, and the drain of the TFT is connected to a terminal (sometimes referred to as a pixel electrode) of a liquid crystal cell Clc represented as a dashed capacitor. Another terminal of the Clc is connected to a common voltage (Vcom). A storage capacitor Cs is also shown as being connected in parallel with the Clc, between the drain of the TFT and Vcom. The TFT, Clc and Cs may be referred to collectively as a pixel. The pixels are arranged in a matrix in the TFT-LCD screen 1016. The GIP driver 1012 has a plurality of gate line outputs G1 to GN that drives the gate lines G1 to GN of the panel TFT-LCD screen 1016 in a sequential manner by providing gate drive pulses, sometime referred to as scan pulses or gate line signals.

The voltage level shifter 1002, which can be one of the voltage level shifters of the above described embodiments of the present invention, converts a low voltage signal from the timing controller 1030 (e.g., 3.3V) to a high voltage signal (e.g., that swings between +20V to −15V). This high voltage signal drives the high voltage shift register(s) in the panel. The outputs of the shift register(s) drive the rows of the panel. For example, the voltage level shifter can shift an “on” pulse from one row to the next, until the end of a frame. Where an LCD panel has 1080 rows, the shift register can shift an “on” pulse from row 1 to row 1080. Depending on the frame rate and refresh rate, as few as one voltage level shifter can be used, or as many as nine or more can be used.

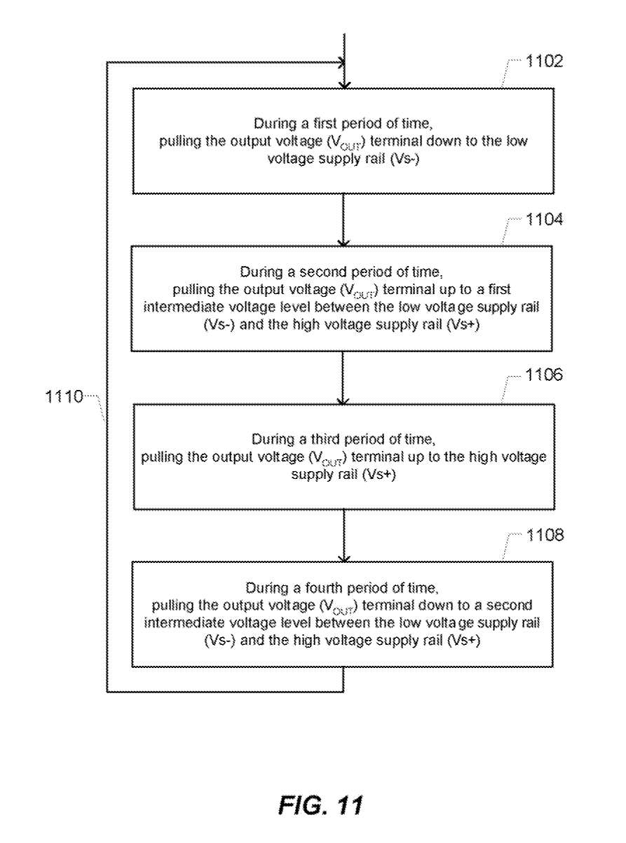

FIG. 11 is a high level flow diagram that is used to summarize methods according to certain embodiments of the present invention. Referring to FIG. 11, during a first period of time (also referred to as a first phase), an output voltage (V_{OUT}) terminal is pulled down to the low voltage supply rail (Vs−), as indicated at step 1102. During a second period of time (also referred to as a second phase), the output voltage (V_{OUT}) terminal is pulled up to a first intermediate voltage level between the low voltage supply rail (Vs−) and the high voltage supply rail (Vs+), as indicated at step 1104. During a third period of time (also referred to as a third phase), the output voltage (V_{OUT}) terminal is pulled up to the high voltage supply rail (Vs+), as indicated at step 1106. During a fourth period of time (also referred to as a fourth phase), the output voltage (V_{OUT}) terminal is pulled down to a second intermediate voltage level between the low voltage supply rail (Vs−) and the high voltage supply rail (Vs+). As indicated by line 1110, steps 1102-1108 are repeated. As was explained above, during the second and fourth periods of time a load connected to the output voltage (V_{OUT}) terminal does not draw any power from the low voltage supply rail (Vs−) and the high voltage supply rail (Vs+). The methods described with reference to FIG. 11 can be used for providing voltage level shifting for use in driving a LCD panel, such as, but not limited to a TFT-LCD panel. The methods described with reference to FIG. 11 can also be used for driving other types of display panels, including, but not limited to, an organic light emitting diode (OLED) panel. In accordance with specific embodiments, the methods also include generating the first and second intermediate voltage levels (referred to at steps 1104 and 1108) using circuitry that is external to the LCD panel, the OLED panel, or alternative type of display panel. This enables the intermediate voltage levels to be precisely controlled, thereby providing for power savings optimization and/or other customization when using these methods with various different display panels (e.g., manufactured by various different manufacturers).

Specific embodiments of the present invention relate to high voltage level shifters with reduced power consumption, which also results in reduced heat dissipation, which is also desirable. Such reductions in power/heat are achieved using a bi-level switching arrangement. Embodiments of the present invention are also directed to methods for providing voltage level shifting in power and heat efficient manners. Embodiments of the present invention are also directed to systems that include voltage level shifters.

While various embodiments of the present invention have been described above, it should be understood that they have been presented by way of example, and not limitation. It will be apparent to persons skilled in the relevant art that various changes in form and detail can be made therein without departing from the spirit and scope of the invention.

The breadth and scope of the present invention should not be limited by any of the above-described exemplary embodiments, but should be defined only in accordance with the following claims and their equivalents.

1. A voltage level shifter circuit, comprising:
a first switch (S1) connected between a first terminal and an output voltage (V_{OUT}) terminal, wherein the first terminal is configured to be connected to a high voltage supply rail (Vs+);
a second switch (S2) connected between a second terminal and the output voltage (V_{OUT}) terminal, wherein the second terminal is configured to be connected to a low voltage supply rail (Vs−);
a third switch (S3) connected between a compensation voltage (V_{COMP}) node and the output voltage (V_{OUT}) terminal; and
control circuitry configured to control the first, second and third switches (S1, S2 and S3) so that
in a first configuration (config 1) the first switch (S1) is opened, the second switch (S2) is closed, and the third switch (S3) is opened, which causes the output voltage (V_{OUT}) terminal to be pulled down to the low voltage supply rail (Vs−),
in a second configuration (config 2) the first (S1) is opened, the second switch (S2) is opened, and the third switch (S3) is closed, which causes the output voltage (V_{OUT}) terminal to be pulled up to a first intermediate voltage level between the low voltage supply rail (Vs−) and the high voltage supply rail (Vs+),
in a third configuration (config 3) the first switch (S1) is closed, the second switch (S2) is opened, and the third switch (S3) is opened, which causes the output voltage (V_{OUT}) terminal to be pulled up to the high voltage supply rail (Vs+), and
in a fourth configuration (config 4) the first switch (S1) is opened, the second switch (S2) is opened, and the third switch (S3) is closed, which causes the output voltage (V_{OUT}) terminal to be pulled down to a second intermediate voltage level between the low voltage supply rail (Vs−) and the high voltage supply rail (Vs+).

2. The voltage level shifter circuit of claim 1, wherein:
the output voltage (V_{OUT}) terminal outputs a singled ended voltage signal;
the output voltage (V_{OUT}) terminal is for connection to a display panel; and
the compensation voltage (V_{COMP}) node is for connection to compensation circuitry that is external to the display panel, the compensation circuitry including a compensation capacitor (C_{COMP}) connected between the compensation voltage (V_{COMP}) node and a further voltage rail between the high and low voltage supply rails.

3. The voltage level shifter circuit of claim 2, wherein the further voltage rail comprises ground.

4. The voltage level shifter circuit of claim 2, wherein a voltage at the compensation voltage (V_{COMP}) node is dependent on the compensation capacitor (C_{COMP}) connected between the compensation voltage (V_{COMP}) node and the further voltage rail.

5. The voltage level shifter circuit of claim 2, wherein the compensation circuitry also includes a compensation resistor (R_{COMP}) connected in series with the compensation capacitor (C_{COMP}) between the compensation voltage (V_{COMP}) node and the further voltage rail.

6. The voltage level shifter circuit of claim 1, wherein:
the first intermediate voltage level equals (Vs−+V_{COMP})/2; and
the second intermediate voltage level equals (Vs++V_{COMP})/2.

7. The voltage level shifter circuit of claim 1, wherein during the second and fourth configurations (config 2 and config 4) the voltage level shifter circuit does not draw any power from the low voltage supply rail (Vs−) and the high voltage supply rail (Vs+).

8. The voltage level shifter circuit of claim 1, wherein during the second and fourth configurations (config 2 and config 4) a load connected to the output voltage (V_{OUT}) terminal does not draw any power from the low voltage supply rail (Vs−) and the high voltage supply rail (Vs+).

9. The voltage level shifter circuit of claim 1, wherein the control circuitry is configured to receive one or more clock signals that is/are used to control the timing of the switching among the first, second, third and fourth configurations.

10. The voltage level shifter circuit of claim 1, wherein:
the voltage level shifter circuit is implemented as an integrated circuit (IC);
the first switch (S1), the second switch (S2), the third switch (S3) and the control circuitry are implemented within the integrated circuit (IC); and
each one of the first terminal, the second terminal, the output voltage (V_{OUT}) terminal, and the compensation voltage (V_{COMP}) node is a separate terminal of the integrated circuit (IC).

11. The voltage level shifter circuit of claim 10, wherein:
the integrated circuit (IC) also comprises one or more clock input terminals; and
the control circuitry is configured to transition between the first, second, third and fourth configurations in dependence on one or more clock signals that is/are received by the one or more clock input terminals of the integrated circuit (IC).

12. The voltage level shifter circuit of claim 1, wherein a voltage at the compensation voltage (V_{COMP}) node is provided by a power supply.

13. The voltage level shifter circuit of claim 12, wherein the voltage at the compensation voltage (V_{COMP}) node, which is provided by the power supply, equals (Vs++Vs−)/2.

14. The voltage level shifter circuit of claim 12, wherein:
the first switch (S1), the second switch (S2), the third switch (S3), the control circuitry, and at least a portion of the power supply are implemented within an integrated circuit (IC); and
each one of the first terminal, the second terminal and the output voltage (V_{OUT}) terminal is a separate terminal of the integrated circuit (IC).

15. The voltage level shifter circuit of claim 12, wherein:
the first switch (S1), the second switch (S2), the third switch (S3) and the control circuitry are implemented within an integrated circuit (IC);
the power supply is implemented outside the integrated circuit (IC); and
each one of the first terminal, the second terminal, the output voltage (V_{OUT}) terminal, and the compensation voltage (V_{COMP}) node is a separate terminal of the integrated circuit (IC).

16. A voltage level shifter circuit configured to drive a load, comprising:
a first terminal configured to be connected to a high voltage supply rail (Vs+);
a second terminal configured to be connected to a low voltage supply rail (Vs−);
an output voltage (V_{OUT}) terminal connectable to a load to be driven by a single ended voltage signal output at the output voltage (V_{OUT}) terminal;
a compensation voltage (V_{COMP}) node at which are generated intermediate voltage levels between the high voltage supply rail (Vs+) and the low voltage supply rail (Vs−);
a plurality of switches configurable in a plurality of configurations; and
control circuitry configured to control the switches so that in at least one of the configurations a load connected to the output voltage (V_{OUT}) terminal is connected to the compensation voltage (V_{COMP}) node and disconnected from both the low voltage supply rail (Vs−) and the high voltage supply rail (Vs+), and thus, does not draw any power from the low voltage supply rail (Vs−) and the high voltage supply rail (Vs+).

17. The voltage level shifter circuit of claim 16, wherein:
the output voltage (V_{OUT}) terminal is for connection to a display panel; and
the compensation voltage (V_{COMP}) node is for connection to compensation circuitry that is external the display panel, the compensation circuitry including a compensation capacitor (C_{COMP}) connected between the compensation voltage (V_{COMP}) node and a further voltage rail between the high and low voltage supply rails.

18. The voltage level shifter circuit of claim 17, wherein:
the control circuitry is configured to control the switches so that
in a first configuration the output voltage (V_{OUT}) terminal is pulled down to the low voltage supply rail (Vs−),
in a second configuration the output voltage (V_{OUT}) terminal is pulled up to a first intermediate voltage level between the low voltage supply rail (Vs−) and the high voltage supply rail (Vs+), the first intermediate voltage dependent on a voltage at the compensation voltage (V_{COMP}) node,
in a third configuration the output voltage (V_{OUT}) terminal is pulled up to the high voltage supply rail (Vs+),
in a fourth configuration the output voltage (V_{OUT}) terminal is pulled down to a second intermediate voltage level between the low voltage supply rail (Vs−) and the high voltage supply rail (Vs+), the first second intermediate voltage dependent on a voltage at the compensation voltage (V_{COMP}) node, and
during the second and fourth configurations the voltage level shifter circuit does not draw any power from the low voltage supply rail (Vs−) and the high voltage supply rail (Vs+).

19. A method for providing voltage level shifting for use in driving a display panel, the method comprising:
(a) during a first period of time, pulling an output voltage (V_{OUT}) terminal down to the low voltage supply rail (Vs−), the output voltage (V_{OUT}) terminal connectable to the display panel;
(b) during a second period of time, pulling up the output voltage (V_{OUT}) terminal to a first intermediate voltage level between the low voltage supply rail (Vs−) and the high voltage supply rail (Vs+);
(c) during a third period of time, pulling up the output voltage (V_{OUT}) terminal to the high voltage supply rail (Vs+);
(d) during a fourth period of time, pulling down the output voltage (V_{OUT}) terminal to a second intermediate voltage level between the low voltage supply rail (Vs−) and the high voltage supply rail (Vs+); and
(e) generating the first and second intermediate voltage levels using circuitry that is external to the display panel.

20. The method of claim 19, wherein during the second and fourth periods of time a load connected to the output voltage (V_{OUT}) terminal does not draw any power from the low voltage supply rail (Vs−) and the high voltage supply rail (Vs+).

21. A system comprising:
a display panel including a column driver, a gate driver and a display screen driven by outputs of the column driver and the gate driver;
a voltage level shifter that drives the gate driver of the display panel; and
a timing controller that provides at least one clock signal to the voltage level shifter;
wherein the voltage level shifter includes
a first terminal configured to be connected to a high voltage supply rail (Vs+);
a second terminal configured to be connected to a low voltage supply rail (Vs−);
an output voltage (V_{OUT}) terminal connectable to the gate driver of the display panel, which is driven by a voltage signal output at the output voltage (V_{OUT}) terminal;
a compensation voltage (V_{COMP}) node at which are generated intermediate voltage levels between the high voltage supply rail (Vs+) and the low voltage supply rail (Vs−);
a plurality of switches configurable in a plurality of configurations; and
control circuitry configured to control the switches so that in at least one of the configurations a load connected to the output voltage (V_{OUT}) terminal is connected to the compensation voltage (V_{COMP}) node and disconnected from both the low voltage supply rail (Vs−) and the high voltage supply rail (Vs+), and thus, does not draw any power from the low voltage supply rail (Vs−) and the high voltage supply rail (Vs+); and
further comprising compensation circuitry that is external to the display panel, the compensation circuitry including a compensation capacitor (C_{COMP}) connected between the compensation voltage (V_{COMP}) node of the voltage level shifter and a further voltage rail between the high and low voltage supply rails.

22. The system of claim 21, wherein during the second and fourth configurations, the gate driver connected to the output voltage (V_{OUT}) terminal does not draw any power from the low voltage supply rail (Vs−) and the high voltage supply rail (Vs+).
